(19) United States
(12) Patent Application Publication
(10) Pub. No.: US 2026/0371487 A1
(43) Pub. Date: Nov. 19, 2026

(54) WIRING SUBSTRATE

(71) Applicant: IBIDEN CO., LTD., Gifu (JP)

(72) Inventors: Kotaro TAKAGI, Gifu (JP); Yui KUNISHIMA, Gifu (JP)

(73) Assignee: IBIDEN CO., LTD., Gifu (JP)

(21) Appl. No.: 19/674,662

(22) Filed: May 12, 2026

(30) Foreign Application Priority Data
May 14, 2025 (JP) 2025-081571

(51) Int. Cl. H05K 1/11; H05K 1/185

(52) U.S. Cl. CPC H05K 1/115; H05K 1/185

(57) ABSTRACT

A wiring substrate includes a multilayer core substrate, a build-up layer formed on the substrate, and a component embedded in the substrate and positioned on first surface side of the substrate. The substrate includes a central insulating layer, first-surface-side insulating layers formed on first surface side of the central layer, second-surface-side insulating layers formed on second surface side of the central layer, inner-layer conductors formed on the central layer and the first-surface-side and second-surface-side insulating layers, first through holes formed in the substrate such that each first through hole is connected to one or more inner-layer conductors, and second through holes formed in the substrate such that each second through hole is connected to one or more inner-layer conductors and the first and second through holes satisfy H1<H2 where H1 is a length of each first through hole and H2 is a length of each second through hole.

### CROSS-REFERENCE TO RELATED APPLICATIONS

The present application is based upon and claims the benefit of priority to Japanese Patent Application No. 2025-081571, filed May 14, 2025, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2010-166099 describes a printed wiring board in which conductor layers and interlayer resin insulating layers are alternately laminated on a core substrate. The entire contents of this publication are incorporated herein by reference.

### SUMMARY OF THE INVENTION

According to one aspect of the present invention, a wiring substrate includes a multilayer core substrate, a build-up layer formed on the multilayer core substrate, and a component embedded in the multilayer core substrate such that the component is positioned on a first surface side of the multilayer core substrate. The multilayer core substrate includes a central insulating layer, first-surface-side insulating layers formed on a first surface side of the central insulating layer, second-surface-side insulating layers formed on a second surface side of the central insulating layer, inner-layer conductors formed on the central insulating layer and the first-surface-side insulating layers and second-surface-side insulating layers, first through holes formed in the multilayer core substrate such that each of the first through holes is connected to one or more of the inner-layer conductors, and second through holes formed in the multilayer core substrate such that each of the second through holes is connected to one or more of the inner-layer conductors and that the first and second through holes satisfy H1<H2 where H1 is a length of each of the first through holes and H2 is a length of each of the second through holes.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged view of a portion (II) of FIG. 1;

FIG. 3 is an enlarged view of a portion (III) of FIG. 1;

FIG. 4A is a cross-sectional view schematically illustrating a method for manufacturing a wiring substrate according to an embodiment of the present invention;

FIG. 4B is a cross-sectional view schematically illustrating a method for manufacturing a wiring substrate according to an embodiment of the present invention;

FIG. 4C is a cross-sectional view schematically illustrating a method for manufacturing a wiring substrate according to an embodiment of the present invention;

FIG. 4D is a cross-sectional view schematically illustrating a method for manufacturing a wiring substrate according to an embodiment of the present invention;

FIG. 4E is a cross-sectional view schematically illustrating a method for manufacturing a wiring substrate according to an embodiment of the present invention;

FIG. 4F is a cross-sectional view schematically illustrating a method for manufacturing a wiring substrate according to an embodiment of the present invention;

FIG. 4G is a cross-sectional view schematically illustrating a method for manufacturing a wiring substrate according to an embodiment of the present invention;

FIG. 4H is a cross-sectional view schematically illustrating a method for manufacturing a wiring substrate according to an embodiment of the present invention;

FIG. 4I is a cross-sectional view schematically illustrating a method for manufacturing a wiring substrate according to an embodiment of the present invention;

FIG. 4J is a cross-sectional view schematically illustrating a method for manufacturing a wiring substrate according to an embodiment of the present invention;

FIG. 4K is a cross-sectional view schematically illustrating a method for manufacturing a wiring substrate according to an embodiment of the present invention;

FIG. 4L is a plan view schematically illustrating a method for manufacturing a wiring substrate according to an embodiment of the present invention;

FIG. 4M is a plan view schematically illustrating a method for manufacturing a wiring substrate according to an embodiment of the present invention;

FIG. 5 is a cross-sectional view schematically illustrating a wiring substrate of a first modified example according to an embodiment of the present invention;

FIG. 6 is a cross-sectional view schematically illustrating a wiring substrate of a second modified example according to an embodiment of the present invention; and

FIG. 7 is a cross-sectional view schematically illustrating a wiring substrate of a third modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

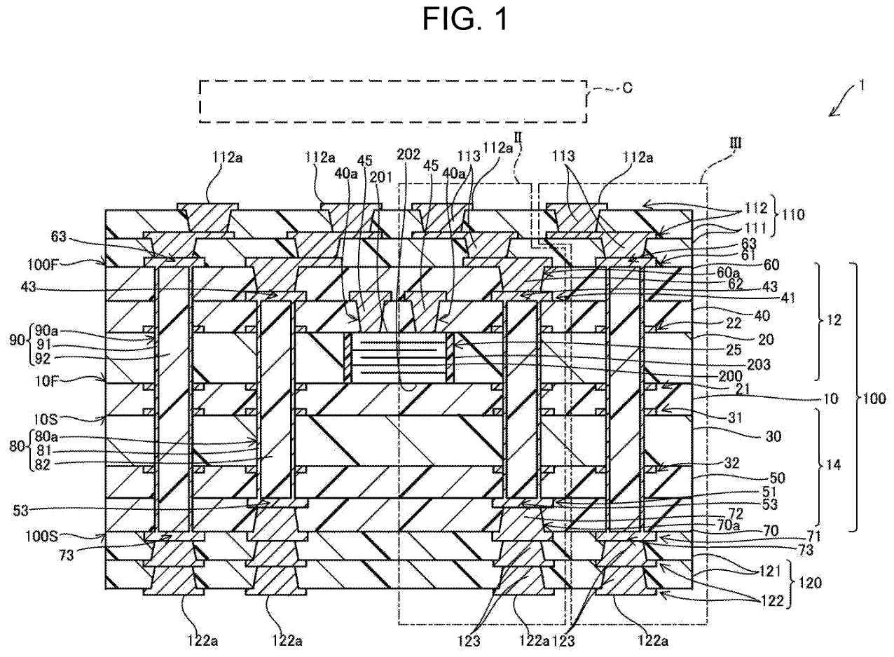

FIG. 1 is a cross-sectional view illustrating a wiring substrate 1 according to an embodiment of the present invention. As illustrated in FIG. 1, the wiring substrate 1 includes a multilayer core substrate 100, a first build-up layer 110, and a second build-up layer 120. The first build-up layer 110 is formed on a first surface (100F) of the multilayer core substrate 100. The second build-up layer 120 is formed on a second surface (100S) of the multilayer core substrate 100. A semiconductor chip (C) is mounted on the first build-up layer 110.

The multilayer core substrate 100 is formed of a central insulating layer 10, a first-surface-side insulating layer 12, and a second-surface-side insulating layer 14, and has multiple first through holes 80, multiple second through holes 90, multiple first via conductors 62, multiple second via conductors 72, inner-layer conductor layers, surface-layer conductor layers, and connection conductors 45. A component 200 is positioned in the multilayer core substrate 100. The first-surface-side insulating layer 12 is formed on a first surface (10F) of the central insulating layer 10. The second-surface-side insulating layer 14 is formed on a second surface (10S) of the central insulating layer 10. The central insulating layer 10 is sandwiched between the first-surface-side insulating layer 12 and the second-surface-side insulating layer 14. The inner-layer conductor layers are a first conductor layer 21, a second conductor layer 22, a fifth conductor layer 41, a third conductor layer 31, a fourth conductor layer 32, and a sixth conductor layer 51, and the surface-layer conductor layers are a seventh conductor layer 61 and an eighth conductor layer 71.

The central insulating layer 10 is formed of a single insulating layer. The central insulating layer 10 is formed of at least one resin substrate or insulating layer. The central insulating layer 10 is not limited in the number of layers, and thus may be formed of two or more resin substrates or insulating layers.

The first-surface-side insulating layer 12 is formed of a first resin substrate 20, a first insulating layer 40, and a third insulating layer 60. The first resin substrate 20 is formed on the first surface (10F) of the central insulating layer 10. The first insulating layer 40 is formed on a surface of the first resin substrate 20 on an opposite side with respect to the central insulating layer 10. The third insulating layer 60 is formed on a surface of the first insulating layer 40 on an opposite side with respect to the first resin substrate 20.

The second-surface-side insulating layer 14 is formed of a second resin substrate 30, a second insulating layer 50, and a fourth insulating layer 70. The second resin substrate 30 is formed on the second surface (10S) of the central insulating layer 10. The second insulating layer 50 is formed on a surface of the second resin substrate 30 on an opposite side with respect to the central insulating layer 10. The fourth insulating layer 70 is formed on a surface of the second insulating layer 50 on an opposite side with respect to the second resin substrate 30.

The first-surface-side insulating layer 12 and the second-surface-side insulating layer 14 are each formed of at least two insulating layers. In other words, the first-surface-side insulating layer 12 and the second-surface-side insulating layer 14 each include at least N insulating layers, where N is an integer of 2 or more. The first-surface-side insulating layer 12 and the second-surface-side insulating layer 14 may each be formed of two insulating layers or four or more insulating layers.

In the description of the wiring substrate 1 of the present embodiment, a side farther from the central insulating layer 10 in a thickness direction of the wiring substrate 1 is also referred to as an “upper side,” “upward,” or “upper,” and a side closer to the central insulating layer 10 is also referred to as a “lower side,” “downward,” or “lower.” Furthermore, for each of the conductor layers and the insulating layers, a surface facing away from the central insulating layer 10 is also referred to as an “upper surface,” and a surface facing toward the central insulating layer 10 is also referred to as a “lower surface.” Therefore, for example, in the description of the first build-up layer 110 and the second build-up layer 120, a side farther from the multilayer core substrate 100 is also referred to as an “upper side,” “upward,” or “upper,” and a side closer to the multilayer core substrate 100 is also referred to as a “lower side,” “downward,” or “lower.” Further, in the description of the wiring substrate 1 of the present embodiment, for each of the conductor layers and the insulating layers, the terms “first surface” and “second surface” may be used. In this case, the first surface is described as an upper surface merely for convenience, and it may be either an upper surface or a lower surface.

The first conductor layer 21 is formed on the lower surface (the surface on the central insulating layer 10 side) of the first resin substrate 20. The first conductor layer 21 is covered by the central insulating layer 10. The second conductor layer 22 is formed on the upper surface (the surface on an opposite side with respect to the central insulating layer 10) of the first resin substrate 20. The second conductor layer 22 is covered by the first insulating layer 40. The first conductor layer 21 and the second conductor layer 22 may each be either a single-layer conductor layer or a multilayer conductor layer of two or more layers. The first conductor layer 21 and the second conductor layer 22 are connected to the first through holes 80 and the second through holes 90. The first conductor layer 21 or the second conductor layer 22 is connected to either the first through holes 80 or the second through holes 90. Alternatively, it is also possible that they are not connected to the first through holes 80 and the second through holes 90.

The third conductor layer 31 is formed on the lower surface (the surface on the central insulating layer 10 side) of the second resin substrate 30. The third conductor layer 31 is covered by the central insulating layer 10. The fourth conductor layer 32 is formed on the upper surface (the surface on an opposite side with respect to the central insulating layer 10) of the second resin substrate 30. The fourth conductor layer 32 is covered by the second insulating layer 50. The third conductor layer 31 and the fourth conductor layer 32 may each be either a single-layer conductor layer or a multilayer conductor layer of two or more layers. The third conductor layer 31 and the fourth conductor layer 32 are connected to the first through holes 80 and the second through holes 90. The third conductor layer 31 and the fourth conductor layer 32 are connected to either the first through holes 80 or the second through holes 90. Alternatively, it is also possible that they are not connected to the first through holes 80 and the second through holes 90.

The fifth conductor layer 41 is formed on the first insulating layer 40. The fifth conductor layer 41 is formed of at least two or more conductor layers. The fifth conductor layer 41 may be formed of three or four conductor layers. The fifth conductor layer 41 is connected to the first through holes 80.

The sixth conductor layer 51 is formed on the second insulating layer 50. The sixth conductor layer 51 is formed of at least two or more conductor layers. The sixth conductor layer 51 may be formed of three or four conductor layers. The sixth conductor layer 51 is connected to the first through holes 80.

The first through holes 80 are formed between the fifth conductor layer 41 and the sixth conductor layer 51. The first through holes 80 are connected to the fifth conductor layer 41 and the sixth conductor layer 51, and are also connected to the first conductor layer 21, the second conductor layer 22, the third conductor layer 31, and the fourth conductor layer 32. That is, the first through holes 80 are connected to six conductor layers.

In the multilayer core substrate 100, the first through holes 80 and the second through holes 90 are each connected to at least one inner-layer conductor layer. In this case, the first through holes 80 and the second through holes 90 may be connected to any of the first conductor layer 21, the second conductor layer 22, the third conductor layer 31, and the fourth conductor layer 32, or may be connected to all of the inner-layer conductor layers. By forming inner-layer conductors in the through holes, electrical characteristics are ensured. Specifically, when the through holes are used as signal lines, high-speed signal transmission can be performed, and when the through holes are used as ground lines or power supply lines, voltage is maintained and power supply is reinforced.

The first through holes 80 are formed of an inner-wall conductor layer 81 and a filler 82. The inner-wall conductor layer 81 is a conductor layer formed on inner walls of through-hole openings (80a). The inner-wall conductor layer 81 may be a single-layer conductor layer or a conductor layer of two or more layers. A surface of the inner-wall conductor layer 81 may be subjected to a surface treatment such as roughening. The filler 82 is formed in the through-hole openings (80a). The through-hole openings (80a) of the first through holes 80 penetrate the central insulating layer 10, the first resin substrate 20, the second resin substrate 30, the first insulating layer 40, and the second insulating layer 50. The through-hole openings (80a) of the first through holes 80 penetrate the central insulating layer 10, and some of the insulating layers of the first-surface-side insulating layer 12 or some of the insulating layers of the second-surface-side insulating layer 14.

In the outermost layer on the first insulating layer 40 side of the first through holes 80, first cover conductors 43 are formed, which serve as a through-hole connection parts between the inner wall conductor layer 81 and the fifth conductor layer 41. The first cover conductors 43 each cover an end surface of the filler 82. The first cover conductors 43 are each a part of the fifth conductor layer 41. In the outermost layer on the second insulating layer 50 side of the first through holes 80, second cover conductors 53 are formed, which serve as a through-hole connection parts between the inner wall conductor layer 81 and the sixth conductor layer 51. The second cover conductors 53 each cover an end surface of the filler 82. The second cover conductors 53 are each a part of the sixth conductor layer 51.

The first through holes 80 are connected to the first conductor layer 21, the second conductor layer 22, the third conductor layer 31, and the fourth conductor layer 32. Openings for forming the first through holes 80 are provided in the first conductor layer 21, the second conductor layer 22, the third conductor layer 31, and the fourth conductor layer 32.

The seventh conductor layer 61 is formed on the third insulating layer 60. The seventh conductor layer 61 is formed of at least two or more conductor layers. The seventh conductor layer 61 may be formed of three or four conductor layers. The seventh conductor layer 61 is connected to the first via conductors 62 and the second through holes 90.

The eighth conductor layer 71 is formed on the fourth insulating layer 70. The eighth conductor layer 71 is formed of at least two or more conductor layers. The eighth conductor layer 71 may be formed of three or four conductor layers. The eighth conductor layer 71 is connected to the second via conductors 72 and the second through holes 90.

The first via conductors 62 are formed in holes (60a) that penetrate the third insulating layer 60 and expose the first cover conductors 43. The first via conductors 62 connect the seventh conductor layer 61 and the first cover conductors 43.

The second via conductors 72 are formed in holes (70a) that penetrate the fourth insulating layer 70 and expose the second cover conductors 53. The second via conductors 72 connect the eighth conductor layer 71 and the second cover conductors 53.

The second through holes 90 are formed between the seventh conductor layer 61 and the eighth conductor layer 71. The second through holes 90 are connected to the seventh conductor layer 61 and the eighth conductor layer 71, and are also connected to the first conductor layer 21, the second conductor layer 22, the third conductor layer 31, and the fourth conductor layer 32. That is, the second through holes 90 are connected to six conductor layers.

The second through holes 90 are formed of an inner-wall conductor layer 91 and a filler 92. The inner-wall conductor layer 91 is a conductor layer formed on inner walls of through-hole openings (90a). The inner-wall conductor layer 91 may be a single-layer conductor layer or a conductor layer of two or more layers. A surface of the inner-wall conductor layer 91 may be subjected to a surface treatment such as roughening. The filler 92 is formed in the through-hole openings (90a). The through-hole openings (90a) of the second through holes 90 penetrate the central insulating layer 10, the first resin substrate 20, the second resin substrate 30, the first insulating layer 40, the second insulating layer 50, the third insulating layer 60, and the fourth insulating layer 70. That is, the through-hole openings (90a) of the second through holes 90 penetrate the central insulating layer 10, the first-surface-side insulating layer 12, and the second-surface-side insulating layer 14.

In the outermost layer on the third insulating layer 60 side of the second through holes 90, third cover conductors 63 are formed, which serve as through-hole connection parts between the inner wall conductor layer 91 and the seventh conductor layer 61. The third cover conductors 63 each cover an end surface of the filler 92. The third cover conductors 63 are each a part of the seventh conductor layer 61. In the outermost layer on the fourth insulating layer 70 side of the second through holes 90, fourth cover conductors 73 are formed, which serve as through-hole connection parts between the inner wall conductor layer 91 and the eighth conductor layer 71. The fourth cover conductors 73 each cover an end surface of the filler 92. The fourth cover conductors 73 are each a part of the eighth conductor layer 71.

The second through holes 90 are connected to the first conductor layer 21, the second conductor layer 22, the third conductor layer 31, and the fourth conductor layer 32. Openings for forming the second through holes 90 are provided in the first conductor layer 21, the second conductor layer 22, the third conductor layer 31, and the fourth conductor layer 32.

The first through holes 80 are formed penetrating the central insulating layer 10, M insulating layers of the first-surface-side insulating layer 12 (where M=an integer between 1 and N−1), and M insulating layers of the second-surface-side insulating layer 14 (where M=an integer between 1 and N−1). Further, the first through holes 80 are connected to inner-layer conductors of one or more layers formed in any of the central insulating layer 10, the first-surface-side insulating layer 12, and the second-surface-side insulating layer 14. By forming inner-layer conductors in the through holes, electrical characteristics are ensured. The first through holes 80 are preferably connected to inner-layer conductors of two or more layers. By forming inner-layer conductors of two or more layers in the first through holes 80, electrical characteristics are ensured and the strength of the substrate can be obtained.

The second through holes 90 are formed penetrating the central insulating layer 10, N insulating layers of the first-surface-side insulating layer 12, and N insulating layers of the second-surface-side insulating layer 14. As a result, a length of the second through holes 90 is longer than a length of the first through holes 80. Further, the second through holes 90 are connected to inner-layer conductors of one or more layers formed in any of the central insulating layer 10, the first-surface-side insulating layer 12, and the second-surface-side insulating layer 14. By forming inner-layer conductors in the through holes, electrical characteristics are ensured. The second through holes 90 are preferably connected to inner-layer conductors of two or more layers. By forming inner-layer conductors of two or more layers in the second through holes 90, electrical characteristics are ensured and the strength of the substrate can be obtained.

The length (H1) of the first through holes 80 and the length (H2) of the second through holes 90 desirably satisfy a relationship of Formula 1, H1<H2.

When the length (H1) of the first through holes 80 and the length (H2) of the second through holes 90 satisfy the relationship of Formula 1, both effects of high-speed signal transmission and power supply reinforcement can be achieved.

In the embodiment, the first through holes 80 are mainly positioned at a center of the wiring substrate 1, and the second through holes 90 are mainly positioned at an outer periphery of the wiring substrate 1. The first through holes 80 serve as power supply lines, and the second through holes 90 serve as signal lines. The first through holes 80 are preferably positioned directly below the semiconductor chip (C) (see FIG. 1) when the semiconductor chip (C) is mounted. By forming the first through holes 80 directly below the semiconductor chip (C), a distance between the semiconductor chip (C) and the first through holes is shortened, electrical characteristics are ensured, voltage from the semiconductor chip (C) is maintained, and power supply is reinforced.

The first through holes 80 and the second through holes 90 are each provided with inner-layer conductors of at least one or more layers. Further, the first through holes 80 and the second through holes 90 are preferably each provided with inner-layer conductors of two or more layers. By forming inner-layer conductors of two or more layers in each of the through holes, electrical characteristics are ensured and the strength of the substrate can be obtained. Here, the first through holes 80 and the second through holes 90 may be provided with inner-layer conductors of the same number of layers or different numbers of layers.

Regarding the inner-layer conductors, the number of layers (D1) of the inner-layer conductors of the first through holes 80 and the number of layers (D2) of the inner-layer conductors of the second through holes 90 may satisfy relationships of Formula 2A, D1=D2, Formula 2B, D1>D2, and Formula 2C, D1<D2.

Even with these Formulas 2A to 2C, both effects of high-speed signal transmission and power supply reinforcement can be achieved.

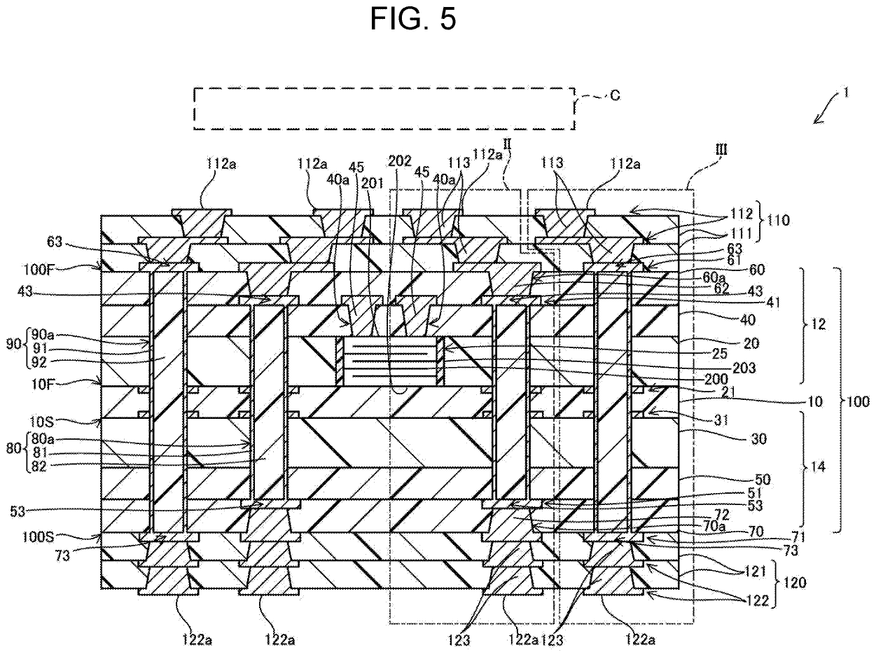

As an example of a formation of inner-layer conductors satisfying Formula 2A, in FIG. 1, the first through holes 80 have inner-layer conductors of four layers and the second through holes 90 have inner-layer conductors of four layers. Other examples include, as in a first modified example illustrated in FIG. 5, a case where the first through holes 80 have inner-layer conductors of two layers and the second through holes 90 have inner-layer conductors of two layers. As long as the relationship of the number of layers satisfies Formula 2A, the inner-layer conductors of the first through holes 80 and the inner-layer conductors of the second through holes 90 may be formed at the same layer positions or at different layer positions in the multilayer core substrate.

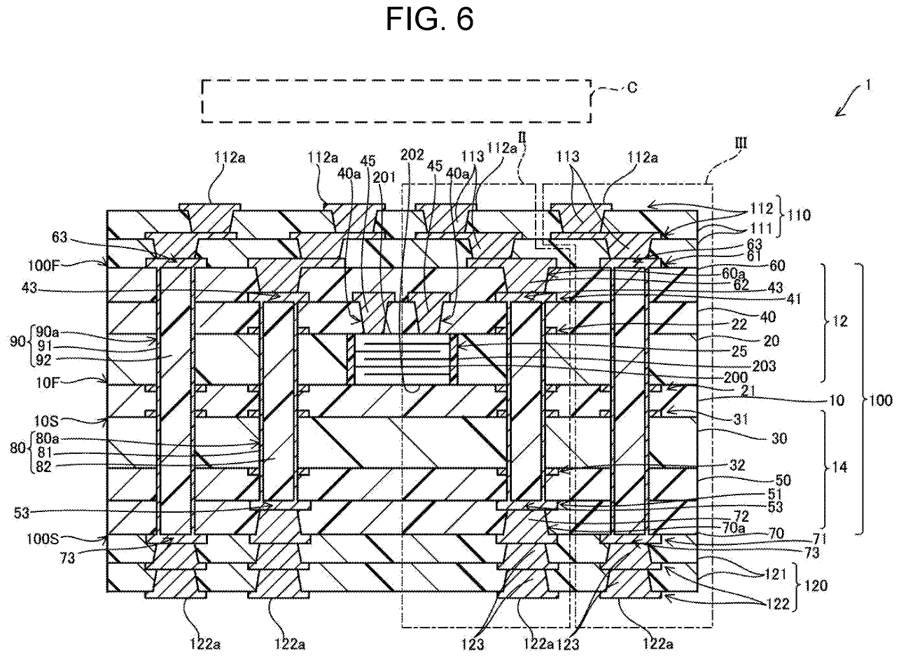

As an example of a formation of inner-layer conductors satisfying Formula 2B, in a second modified example illustrated in FIG. 6, the first through holes 80 have inner-layer conductors of four layers and the second through holes 90 have inner-layer conductors of two layers. As long as the relationship of the number of layers satisfies Formula 2B, the inner-layer conductors of the first through holes 80 and the inner-layer conductors of the second through holes 90 may be formed at the same layer positions or at different layer positions in the multilayer core substrate. Specifically, in the multilayer core substrate, the inner-layer conductors of the first through holes 80 may be provided at one or more layer positions that are the same as the layer positions of the inner-layer conductors of the second through holes 90, or may not be provided at any layer position that is the same as the layer positions of the inner-layer conductors of the second through holes 90. Since the formation of inner-layer conductors satisfying Formula 2B can be appropriately determined according to design factors such as diameters of the through holes and the size of the substrate, both effects of high-speed signal transmission and power supply reinforcement can be achieved.

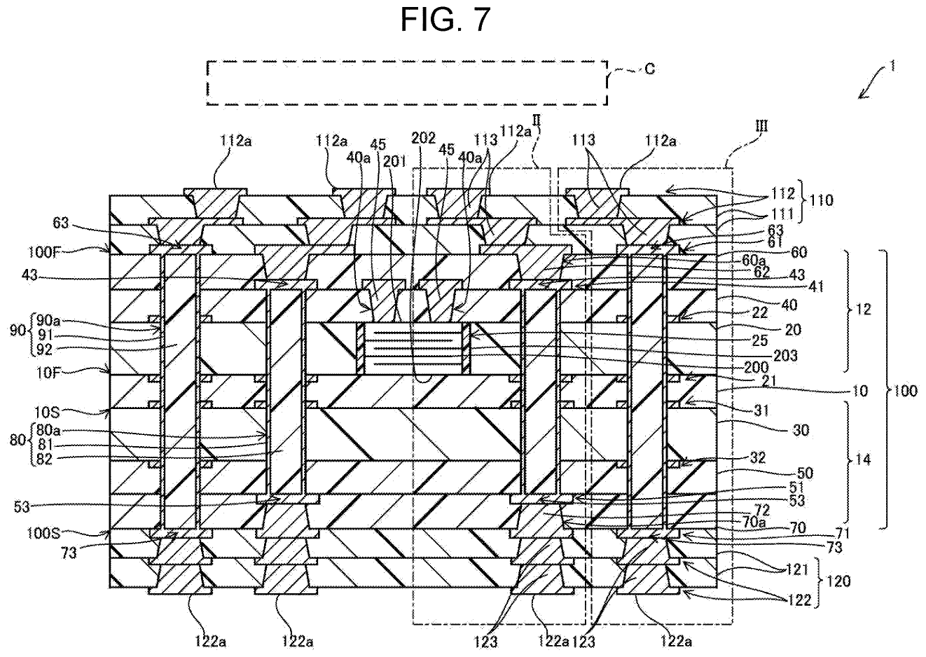

As an example of a formation of inner-layer conductors satisfying Formula 2C, in a third modified example illustrated in FIG. 7, the first through holes 80 have inner-layer conductors of two layers and the second through holes 90 have inner-layer conductors of four layers. As long as the relationship of the number of layers satisfies Formula 2C, the inner-layer conductors of the first through holes 80 and the inner-layer conductors of the second through holes 90 may be formed at the same layer positions or at different layer positions in the multilayer core substrate. Specifically, in the multilayer core substrate, the inner-layer conductors of the second through holes 90 may be provided at one or more layer positions that are the same as the layer positions of the inner-layer conductors of the first through holes 80, or may not be provided at any layer position that is the same as the layer positions of the inner-layer conductors of the first through holes 80. Since the formation of inner-layer conductors satisfying Formula 2C can be appropriately determined according to design factors such as diameters of the through holes and the size of the substrate, both effects of high-speed signal transmission and power supply reinforcement can be achieved.

An opening diameter of the first through holes 80 is not particularly limited, but is desirably 50 to 300 μm. An opening diameter of the second through holes 90 is not particularly limited, but is desirably 50 to 300 μm. The opening diameter of the first through holes 80 and the opening diameter of the second through holes 90 may be the same or different. The opening diameter of the through holes refers to the diameter of the through-hole openings before the inner-wall conductor layer is formed.

A pitch of the first through holes 80 is not particularly limited, but is desirably 50 to 400 μm. The pitch of the first through holes 80 may be uniform or non-uniform. The pitch of the first through holes 80 is preferably uniform, as this facilitates reliable assurance of electrical characteristics associated with current flow through the through holes. Here, the pitch of the first through holes 80 refers to a shortest distance between two adjacent first through holes 80.

A pitch of the second through holes 90 is not particularly limited, but is desirably 500 to 1000 μm. The pitch of the second through holes 90 may be uniform or non-uniform. The pitch of the second through holes 90 is preferably uniform, as this facilitates reliable assurance of electrical characteristics associated with current flow through the through holes. Here, the pitch of the second through holes 90 refers to a shortest distance between two adjacent second through holes 90.

Furthermore, the pitch of the first through holes 80 is desirably shorter than the pitch of the second through holes 90. By making the pitch of the first through holes 80 shorter than the pitch of the second through holes 90, it becomes easier to ensure electrical characteristics associated with current flow through the through holes. Here, when the first through holes 80 are used as ground lines or power supply lines and the second through holes 90 are used as signal lines, by making the pitch of the first through holes 80 shorter than the pitch of the second through holes 90, voltage can be maintained, power supply can be reinforced, and high-speed signal transmission can be achieved.

A density of the first through holes 80 may be uniform or non-uniform. The density of the first through holes 80 is preferably uniform, as this facilitates reliable assurance of electrical characteristics associated with current flow through the through holes. Here, the density of the first through holes 80 refers to the number of through holes per unit area.

A density of the second through holes 90 may be uniform or non-uniform. The density of the second through holes 90 is preferably uniform, as this facilitates reliable assurance of electrical characteristics associated with current flow through the through holes. Here, the density of the second through holes 90 refers to the number of through holes per unit area.

Furthermore, the density of the first through holes 80 is desirably higher than the density of the second through holes 90. By making the density of the first through holes 80 higher than the density of the second through holes 90, it becomes easier to ensure electrical characteristics associated with current flow through the through holes. Here, when the first through holes 80 are used as ground lines or power supply lines and the second through holes 90 are used as signal lines, by making the density of the first through holes 80 higher than the density of the second through holes 90, voltage can be maintained, power supply can be reinforced, and high-speed signal transmission can be achieved.

The component 200 is embedded on the first surface side of the multilayer core substrate 100. The component 200 is positioned in the first-surface-side insulating layer 12. An opening 25 penetrating the first resin substrate 20 is formed in the first resin substrate 20. The component 200 is accommodated in the opening 25. The component 200 is an electronic component. Specifically, the electronic component is a capacitor, an inductor, an IVR, a semiconductor, or the like. The component 200 has an electrode surface 201 and a non-electrode surface 202 on an opposite side with respect to the electrode surface 201. The non-electrode surface 202 of the component 200 faces the first surface (10F) of the central insulating layer 10. The electrode surface 201 of the component 200 faces the first insulating layer 40. The connection conductors 45 penetrating the first insulating layer 40 are formed in the insulating layer. The connection conductors 45 are connected to a through-hole non-connection portion of the fifth conductor layer 41. The electrode surface 201 is connected to the connection conductors 45. As a result, the electrode surface 201 of the component 200 is connected to the through-hole non-connection portion of the fifth conductor layer 41 via the connection conductors 45. A gap between an inner surface of the opening 25 and the component 200 is filled with an embedding resin 203. The embedding resin 203 is, for example, a thermosetting resin. The embedding resin 203 may also be a photocurable resin. The embedding resin 203 is provided separately from the central insulating layer 10, the first resin substrate 20, and the first insulating layer 40. Multiple components 200 may be accommodated in the opening 25, and identical components or different components may be positioned therein.

The first build-up layer 110 and the second build-up layer 120 are formed on the multilayer core substrate 100. The first build-up layer 110 is formed on the first surface (100F) of the multilayer core substrate 100 and is constituted by at least one or more build-up layers each including an insulating layer 111, a conductor layer 112, and via conductors 113. The second build-up layer 120 is formed on the second surface (100S) of the multilayer core substrate 100 and is constituted by at least one or more build-up layers each including an insulating layer 121, a conductor layer 122, and via conductors 123.

In the example of FIG. 1, the first build-up layer 110 is constituted by two insulating layers 111 and two conductor layers 112, and the second build-up layer 120 is constituted by two insulating layers 121 and two conductor layers 122. Each insulating layer 111 includes via conductors 113 that connect a conductor layer on the insulating layer 111 to a conductor layer below the insulating layer 111. Each insulating layer 121 includes via conductors 123 that connect a conductor layer on the insulating layer 121 to a conductor layer below the insulating layer 121. It is also possible that a build-up layer is formed only on one side of the multilayer core substrate. In this case, only the first build-up layer 110 or only the second build-up layer 120 is formed on the multilayer core substrate.

In the illustrated example, the first build-up layer 110 and the second build-up layer 120 each include two conductor layers and two insulating layers. However, it is also possible that the first build-up layer 110 and the second build-up layer 120 each include three or more conductor layers and three or more insulating layers, or each include only one conductor layer and one insulating layer.

Connection pads (112a) are formed in the conductor layer 112 that is on the surface side in the first build-up layer 110 and is positioned as an outermost layer of the wiring substrate 1, and connection pads (122a) are formed in the conductor layer 122 that is on the surface side in the second build-up layer 120 and is positioned as an outermost layer of the wiring substrate 1. An external electronic component, a motherboard (not illustrated), or the like is mounted on the connection pads (112a). When an electronic component is mounted, bumps (not illustrated) formed of any metal such as solder, copper, or tin are formed on the connection pads (112a) or the connection pads (122a).

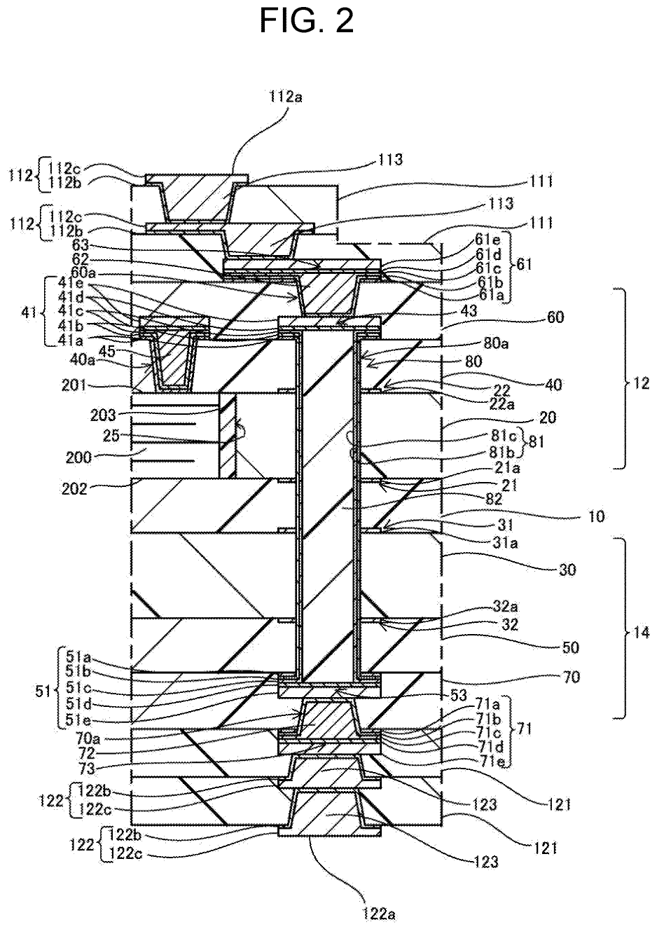

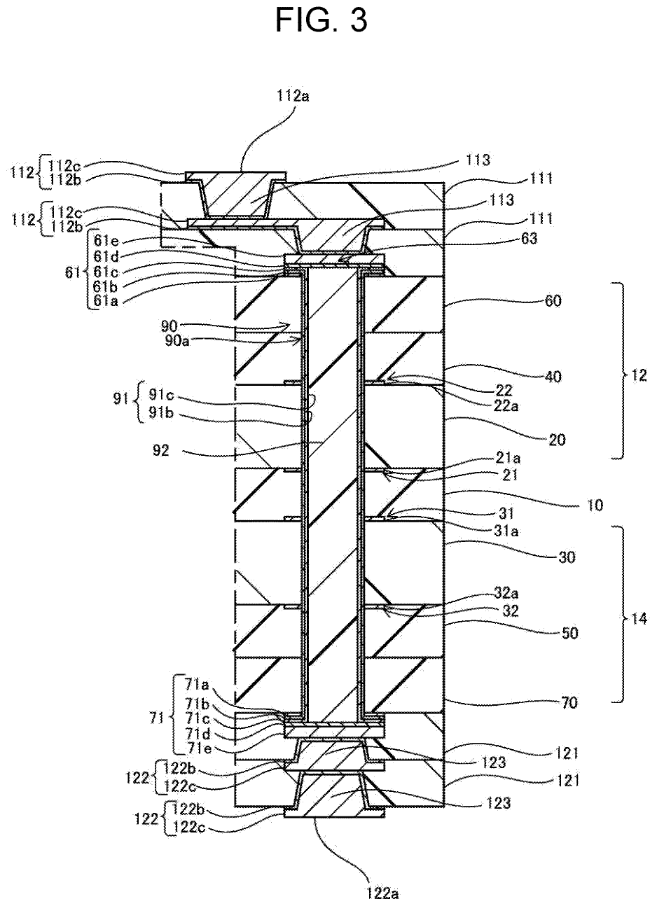

In the wiring substrate 1, the first conductor layer 21, the second conductor layer 22, the third conductor layer 31, the fourth conductor layer 32, the fifth conductor layer 41, the sixth conductor layer 51, the seventh conductor layer 61, the eighth conductor layer 71, the conductor layers 112 in the first build-up layer 110, and the conductor layers 122 in the second build-up layer 120 are each formed with any conductor patterns. These conductor layers are illustrated in a simplified manner as each having a single-layer structure for ease of viewing; however, as will be described later with reference to FIGS. 2 and 3, these conductor layers may each have a multilayer structure including two or more layers.

The insulating layers and resin substrates that constitute the multilayer core substrate 100 according to an embodiment of the present invention are not particularly limited, but are desirably each obtained by impregnating a core material serving as a reinforcing material with an insulating resin and curing the same. As the insulating resin, an epoxy resin, a bismaleimide triazine resin (BT resin), a phenol resin, or the like can be used. Examples of the reinforcing material include glass fiber, aramid fiber, glass nonwoven fabric, aramid nonwoven fabric, and the like. By containing a core material in the insulating layers and resin substrates, a wiring substrate 1 with high rigidity and suppressed warpage is provided. On the other hand, the insulating layers 111 and insulating layers 121 used as build-up layers are preferably formed of an insulating resin that does not contain a core material. This is because an insulating resin that does not contain a core material is suitable for via formation. Further, the insulating layers may each contain an inorganic filler such as silica.

With reference to FIGS. 2 and 3, structures of the conductors included in the wiring substrate 1 are described in detail. FIG. 2 illustrates an enlarged view of a portion (II) of FIG. 1. FIG. 3 illustrates an enlarged view of a portion (III) of FIG. 1.

FIGS. 2 and 3 illustrate the first conductor layer 21, the second conductor layer 22, the third conductor layer 31, and the fourth conductor layer 32. The first conductor layer 21 is formed of a metal foil layer (21a) formed on the lower surface (the surface on the central insulating layer 10 side) of the first resin substrate 20. The second conductor layer 22 is formed of a metal foil layer (22a) formed on the upper surface (the surface on an opposite side with respect to the central insulating layer 10) of the first resin substrate 20. The third conductor layer 31 is formed of a metal foil layer (31a) formed on the lower surface (the surface on the central insulating layer 10 side) of the second resin substrate 30. The fourth conductor layer 32 is formed of a metal foil layer (32a) formed on the upper surface (the surface on an opposite side with respect to the central insulating layer 10) of the second resin substrate 30. The metal foil layers (21a, 22a, 31a, 32a) each have a single-layer structure, but may have a multilayer structure including two or more layers. The type of metal foil used for the metal foil layers (21a, 22a, 31a, 32a) is not particularly limited, but it is preferable to use one containing copper as a main component in view of conductivity. Instead of the metal foil layer, a seed layer formed of a seed film formed by electroless plating or sputtering may be used.

The conductor layers according to an embodiment of the present invention are constituted by any combination of a metal foil layer, a seed layer, and an electrolytic plating layer. The metal foil layer is a conductor layer formed by patterning a metal foil formed on an insulating layer. The type of metal used for the metal foil is not particularly limited, but it is preferable to use one containing copper as a main component in view of conductivity. The seed layer is a conductor layer formed by patterning a seed film such as an electroless plating film or a sputtering film formed on an entire surface of a substrate. The type of metal for the seed film is not particularly limited, but it is preferable to use one containing copper, nickel, or titanium as a main component. The electrolytic plating layer is a conductor layer formed by patterning a resist on a seed film formed on a substrate and depositing an electrolytic plating film in regions where the resist is not formed. The type of metal in the electrolytic plating film is not particularly limited, but it is preferable to use one containing copper as a main component in view of conductivity.

As illustrated in FIG. 2, the fifth conductor layer 41 is formed of a metal foil layer, a seed layer, and an electrolytic plating layer. Specifically, the fifth conductor layer 41 is formed of a metal foil layer (41a) formed on the upper surface of the first insulating layer 40, a seed layer (41b) on the metal foil layer (41a), an electrolytic plating layer (41c) on the seed layer (41b), a seed layer (41d) on the electrolytic plating layer (41c), and an electrolytic plating layer (41e) on the seed layer (41d). The fifth conductor layer 41 has a five-layer structure including the metal foil (41a), the seed layer (41b), the electrolytic plating layer (41c), the seed layer (41d), and the electrolytic plating layer (41e). Further, the first cover conductors 43 are formed of the seed layer (41d) and the electrolytic plating layer (41e).

The connection conductors 45 are formed in holes (40a) that penetrate the first insulating layer 40 and expose the electrode surface 201 of the component 200. The connection conductors 45 are formed of a seed layer (41b) formed on inner wall surfaces of the holes (40a) and on the electrode surface 201, an electrolytic plating layer (41c) formed on the seed layer (41b) and filling the holes (40a), a seed layer (41d) on the electrolytic plating layer (41c), and an electrolytic plating layer (41e) on the seed layer (41d). The seed layer (41b), the electrolytic plating layer (41c), the seed layer (41d), and the electrolytic plating layer (41e) that form the connection conductors 45 are common to the seed layer (41b), the electrolytic plating layer (41c), the seed layer (41d), and the electrolytic plating layer (41e) that form the fifth conductor layer 41. The fifth conductor layer 41 and the connection conductors 45 are formed simultaneously. The connection conductors 45 connect the electrode surface 201 of the component 200 and the through-hole non-connection portion of the fifth conductor layer 41.

The sixth conductor layer 51 is formed of a metal foil layer, a seed layer, and an electrolytic plating layer. Specifically, the sixth conductor layer 51 is formed of a metal foil layer (51a) formed on the upper surface of the second insulating layer 50, a seed layer (51b) on the metal foil layer (51a), an electrolytic plating layer (51c) on the seed layer (51b), a seed layer (51d) on the electrolytic plating layer (51c), and an electrolytic plating layer (51e) on the seed layer (51d). The sixth conductor layer 51 has a five-layer structure including the metal foil (51a), the seed layer (51b), the electrolytic plating layer (51c), the seed layer (51d), and the electrolytic plating layer (51e). Further, the second cover conductors 53 are formed of the seed layer (51d) and the electrolytic plating layer (51e).

The first through holes 80 are formed of an inner-wall conductor layer 81 and a filler 82. The inner-wall conductor layer 81 of the first through holes 80 is formed of a seed layer (81b) formed on the inner wall surfaces of the through-hole openings (80a) and an electrolytic plating layer (81c) on the seed layer (81b). The seed layer (81b) is common to the seed layers (41b, 51b) and is formed simultaneously with the seed layers (41b, 51b). The electrolytic plating layer (81c) is common to the electrolytic plating layers (41c, 51c) and is formed simultaneously with the electrolytic plating layers (41c, 51c). The first through holes 80 are filled with the filler 82. The filler 82 is formed using an insulating material containing, for example, a resin such as epoxy resin, acrylic resin, or phenolic resin. Alternatively, the filler 82 may be a solidified conductive paste or conductive ink containing metal particles of silver, copper, or the like. By forming the filler 82 in the first through holes 80, it becomes possible to form via conductors directly on the first through holes 80. The first cover conductors 43 and the second cover conductors 53 are formed so as to cover the end surfaces of the filler 82. A conductive material may be used for the filler 82.

As illustrated in FIGS. 2 and 3, the seventh conductor layer 61 is formed of a metal foil layer, a seed layer, and an electrolytic plating layer. Specifically, the seventh conductor layer 61 is formed of a metal foil layer (61a) formed on the upper surface of the third insulating layer 60, a seed layer (61b) on the metal foil layer (61a), an electrolytic plating layer (61c) on the seed layer (61b), a seed layer (61d) on the electrolytic plating layer (61c), and an electrolytic plating layer (61e) on the seed layer (61d). The seventh conductor layer 61 has a five-layer structure including the metal foil (61a), the seed layer (61b), the electrolytic plating layer (61c), the seed layer (61d), and the electrolytic plating layer (61e).

The eighth conductor layer 71 is formed of a metal foil layer, a seed layer, and an electrolytic plating layer. Specifically, the eighth conductor layer 71 is formed of a metal foil layer (71a) formed on the upper surface of the fourth insulating layer 70, a seed layer (71b) on the metal foil layer (71a), an electrolytic plating layer (71c) on the seed layer (71b), a seed layer (71d) on the electrolytic plating layer (71c), and an electrolytic plating layer (71e) on the seed layer (71d). The eighth conductor layer 71 has a five-layer structure including the metal foil (71a), the seed layer (71b), the electrolytic plating layer (71c), the seed layer (71d), and the electrolytic plating layer (71e).

As illustrated in FIG. 2, the first via conductors 62 are formed in the holes (60a) that penetrate the third insulating layer 60 and expose the first cover conductors 43. The first via conductors 62 are formed of a seed layer (61b) formed on inner surfaces of the holes (60a) and an electrolytic plating layer (61c) formed on the seed layer (61b) and filling the holes (60a). The seed layer (61b) and the electrolytic plating layer (61c) that form the first via conductors 62 are common to the seed layer (61b) and the electrolytic plating layer (61c) that form the seventh conductor layer 61. The seventh conductor layer 61 and the first via conductors 62 are formed simultaneously.

Similarly, the second via conductors 72 are formed in the holes (70a) that penetrate the fourth insulating layer 70 and expose the second cover conductors 53. The second via conductors 72 are formed of a seed layer (71b) formed on inner surfaces of the holes (70a) and an electrolytic plating layer (71c) formed on the seed layer (71b) and filling the holes (70a). The seed layer (71b) and the electrolytic plating layer (71c) that form the second via conductors 72 are common to the seed layer (71b) and the electrolytic plating layer (71c) that form the eighth conductor layer 71. The eighth conductor layer 71 and the second via conductors 72 are formed simultaneously.

As illustrated in FIG. 3, the second through holes 90 are formed of the inner-wall conductor layer 91 and the filler 92. The inner-wall conductor layer 91 of the second through holes 90 is formed of a seed layer (91b) formed on the inner wall surfaces of the through-hole openings (90a) and an electrolytic plating layer (91c) on the seed layer (91b). The seed layer (91b) is common to the seed layers (61b, 71b) and is formed simultaneously with the seed layers (61b, 71b). The electrolytic plating layer (91c) is common to the electrolytic plating layers (61c, 71c) and is formed simultaneously with the electrolytic plating layers (61c, 71c). The second through holes 90 are filled with the filler 92. The filler 92 is formed using an insulating material containing, for example, a resin such as epoxy resin, acrylic resin, or phenolic resin. Alternatively, the filler 92 may be a solidified conductive paste or conductive ink containing metal particles of silver, copper, or the like. By forming the filler 92 in the second through holes 90, it becomes possible to form via conductors directly on the second through holes 90. The third cover conductors 63 and the fourth cover conductors 73 are formed so as to cover the end surfaces of the filler 92. A conductive material may be used for the filler 92.

As illustrated in FIGS. 2 and 3, the conductor layers 112 of the first build-up layer 110 are each formed of a seed layer (112b) and an electrolytic plating layer (112c), and each include two conductor layers. The conductor layers 122 of the second build-up layer 120 are each formed of a seed layer (122b) and an electrolytic plating layer (122c), and each include two conductor layers.

The via conductors 113 in the first build-up layer 110 are each formed of a seed layer (112b) and an electrolytic plating layer (112c), and each include two conductor layers. The seed layer (112b) and electrolytic plating layer (112c) of the via conductors 113 are common to the seed layer (112b) and electrolytic plating layer (112c) of the conductor layers 112. The via conductors 123 in the second build-up layer 120 are each formed of a seed layer (122b) and an electrolytic plating layer (122c), and each include two conductor layers. The seed layer (122b) and electrolytic plating layer (122c) of the via conductors 123 are common to the seed layer (122b) and electrolytic plating layer (122c) of the conductor layers 122.

### Method for Manufacturing Wiring Substrate

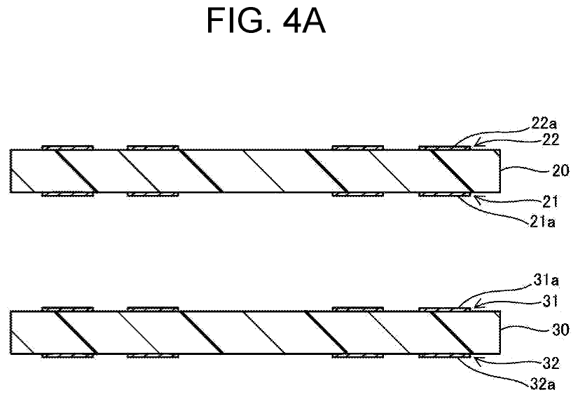

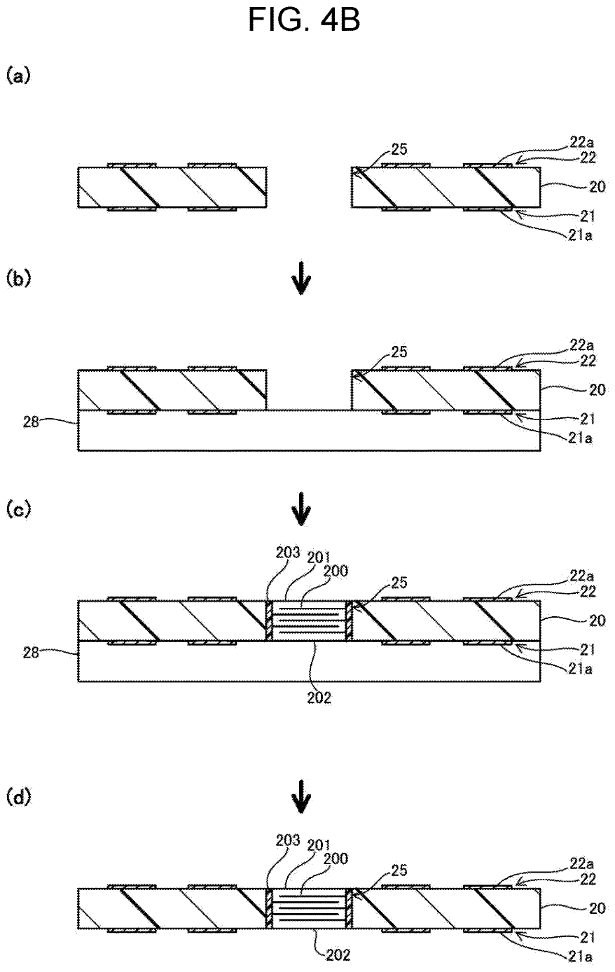

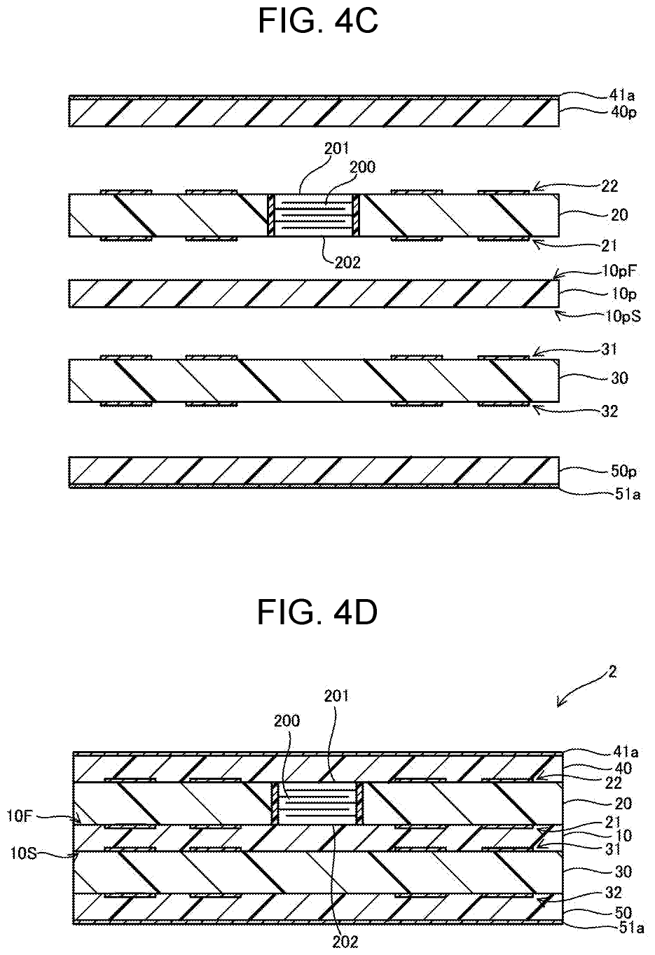

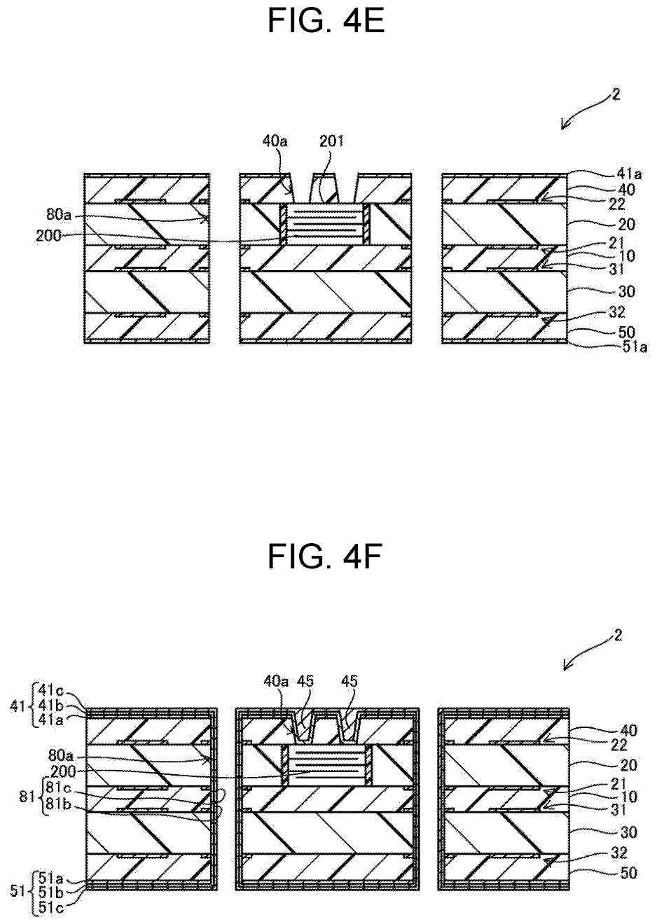

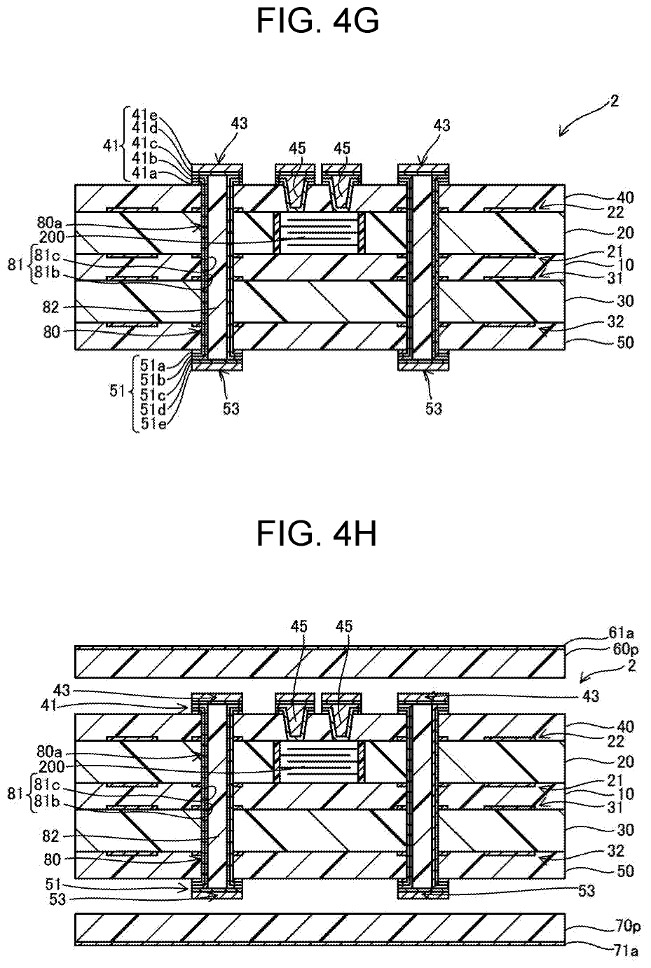

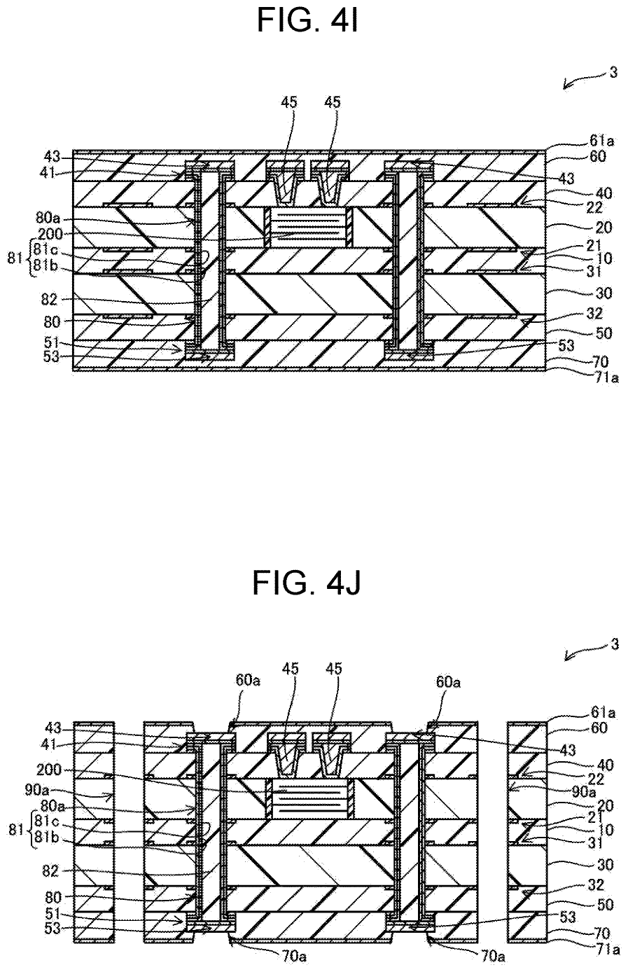

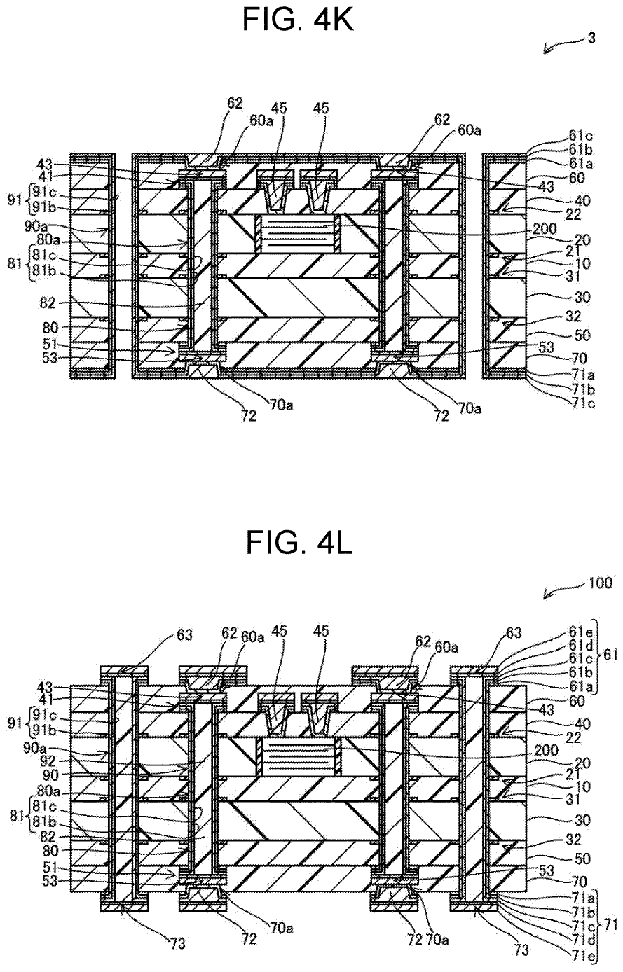

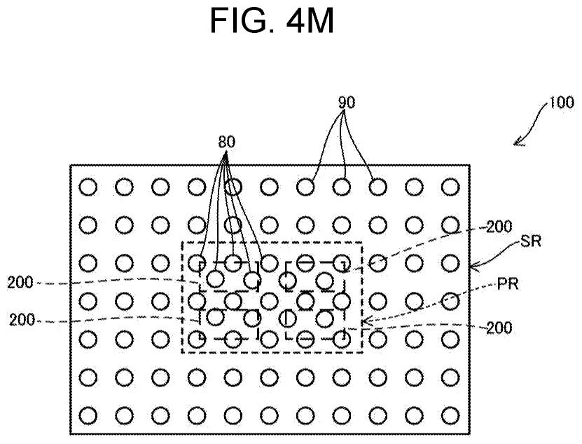

FIG. 4A-4M illustrate a method for manufacturing the wiring substrate 1 according to an embodiment of the present invention. FIG. 4A-4L are cross-sectional views. FIG. 4M is a plan view. As illustrated in FIG. 4A, the first resin substrate 20 is prepared with the first conductor layer 21 formed on its lower surface and the second conductor layer 22 formed on its upper surface. The first resin substrate 20 is prepared using, as a starting material, a double-sided copper-clad laminate in which the metal foils (21a, 22a) are formed on both surfaces of a resin substrate containing a core material. The first conductor layer 21 and the second conductor layer 22 having desired conductor patterns are formed using a subtractive method that involves subjecting the metal foils (21a, 22a) to etching using a mask on which wiring patterns are drawn. Similarly, the second resin substrate 30 is also prepared with the third conductor layer 31 formed on one of its surfaces and the fourth conductor layer 32 formed on the other surface.

As illustrated in FIG. 4B(a), the opening 25 is formed in the first resin substrate 20. The opening 25 penetrates between the upper surface and the lower surface of the first resin substrate 20. The opening 25 is formed using a laser, a router, or the like.

As illustrated in FIG. 4B(b), the first resin substrate 20 having the opening 25 formed therein is placed on a support plate 28. The lower surface of the first resin substrate 20 faces the support plate 28. A lower surface side of the opening 25 in the first resin substrate 20 is closed by the support plate 28. The lower surface of the first resin substrate 20 and the support plate 28 may be bonded via a release agent.

As illustrated in FIG. 4B(c), the component 200 is positioned in the opening 25. The non-electrode surface 202 of the component 200 is positioned on the support plate 28 exposed from the opening 25. In this case, by providing an adhesive layer between the non-electrode surface 202 of the component 200 and the support plate 28, the component 200 is fixed on the support plate 28. The electrode surface 201 of the component 200 is flush with the upper surface of the first resin substrate 20. It is also possible that the electrode surface 201 of the component 200 is lower than the upper surface of the first resin substrate 20. The gap between the opening 25 of the first resin substrate 20 and the component 200 is filled with the embedding resin 203. The filling of the embedding resin 203 is performed, for example, by potting. The embedding resin 203 is preferably a thermosetting resin or a photocurable resin. The embedding resin 203 is cured. The component 200 is fixed in the opening 25.

As illustrated in FIG. 4B(d), the support plate 28 is removed after the embedding resin 203 is cured. The first resin substrate 20 in which the component 200 is accommodated is formed.

As illustrated in FIG. 4C, a prepreg (40p) to be cured into the first insulating layer 40, the first resin substrate 20 in which the component 200 is accommodated, a prepreg (10p) to be cured into the central insulating layer 10, the second resin substrate 30, and a prepreg (50p) to be cured into the second insulating layer 50 are laminated and formed. Specifically, the first resin substrate 20 is formed on a first surface (10pF) side of the prepreg (10p), and the prepreg (40p) is formed on the first resin substrate 20. The second resin substrate 30 is formed on a second surface (10pS) side of the prepreg (10p), and the prepreg (50p) is formed on the second resin substrate 30. The metal foil (41a) is formed on the prepreg (40p). The metal foil (51a) is formed on the prepreg (50p). The first conductor layer 21 faces the first surface (10pF). The second conductor layer 22 faces the prepreg (40p). The third conductor layer 31 faces the second surface (10pS) of the prepreg (10p). The fourth conductor layer 32 faces the prepreg (50p).

As illustrated in FIG. 4D, the prepreg (40p), the first resin substrate 20, the prepreg (10p), the second resin substrate 30, and the prepreg (50p) are stacked in the position illustrated in FIG. 4C and then collectively pressed. Thermal curing may be performed simultaneously with the collective pressing, or after the pressing. Through the collective pressing, the prepregs (10p, 40p, 50p) are cured into the central insulating layer 10, the first insulating layer 40, and the second insulating layer 50. The first conductor layer 21 and the third conductor layer 31 after the pressing are embedded in the central insulating layer 10. The second conductor layer 22 after the pressing is embedded in the first insulating layer 40. The fourth conductor layer 32 after the pressing is embedded in the second insulating layer 50. A laminated substrate 2 including the first insulating layer 40, the first resin substrate 20, the central insulating layer 10, the second resin substrate 30, and the second insulating layer 50 is formed.

In this case, thicknesses of the insulating layers on the first surface (10F) side of the central insulating layer 10 (the first resin substrate 20 and the first insulating layer 40) and thicknesses of the insulating layers on the second surface (10S) side (the second resin substrate 30 and the second insulating layer 50) are set to the same thickness for convenience of description. The thicknesses of the insulating layers on the first surface (10F) side and the thicknesses of the insulating layers on the second surface (10S) side may be different. Specifically, the thicknesses of the insulating layers on the first surface (10F) side may be made smaller than the thicknesses of the insulating layers on the second surface (10S) side. As a result, an overall thickness of the multilayer core substrate can be adjusted. When a component is positioned in a resin substrate, the thicknesses can also be adjusted according to a thickness of the component.

As illustrated in FIG. 4E, the through-hole openings (80a) are formed in the laminated substrate 2. The through-hole openings (80a) are formed penetrating the metal foil (41a), the first insulating layer 40, the second conductor layer 22, the first resin substrate 20, the first conductor layer 21, the central insulating layer 10, the third conductor layer 31, the second resin substrate 30, the fourth conductor layer 32, the second insulating layer 50, and the metal foil (51a) of the laminated substrate 2. The through-hole openings (80a) are formed, for example, by drilling using a cutting device such as a drill. The through-hole openings (80a) may also be formed by laser irradiation. Furthermore, the holes (40a) that penetrate the metal foil (41a) and the first insulating layer 40 and expose the electrode surface 201 of the component 200 are formed. The holes (40a) are formed, for example, by laser irradiation.

As illustrated in FIG. 4F, conductors are formed in the through-hole openings (80a) of the laminated substrate 2. A seed film is formed on the metal foil of the laminated substrate 2 and on inner walls of the through-hole openings. Specifically, the seed film (41b) is formed on the metal foil (41a) of the laminated substrate 2, the seed film (81b) is formed on the inner walls of the through-hole openings (80a), and the seed film (51b) is formed on the metal foil (51a). At the same time, a seed film (41b) is formed on the inner walls of the holes (40a). The seed films (41b, 81b, 51b) are formed simultaneously, and the metal films are formed, for example, by electroless plating or sputtering. An electrolytic plating film is formed using a metal layer serving as a seed film as a power feeding layer. The electrolytic plating films (41c, 81c, 51c) are formed on the seed films. The inner-wall conductor layer 81 formed of the seed film (81b) and the electrolytic plating film (81c) is formed on the inner walls of the through-hole openings. The electrolytic plating film (41c) fills the holes (40a). The connection conductors 45 are formed of the seed layer (41b) formed on the inner walls of the holes (40a) and the electrolytic plating layer (41c) filling the holes (40a).

The filler 82 is filled in cavities of the through-hole openings (80a). For example, a resin such as epoxy resin, acrylic resin, or phenolic resin is injected into each through-hole opening (80a) from one or both ends. The through-hole openings (80a) may be filled with, for example, a conductive paste containing conductive particles such as silver particles, instead of an insulating resin such as epoxy resin, as the filler 82. The insulating resin such as epoxy resin or the conductive paste used for the filler 82 is solidified, by heating or the like when necessary, to form the filler 82. The first through holes 80 are formed of the inner-wall conductor layer 81 and the filler 82 in the through-hole openings (80a). The end surfaces of the filler 82 after solidification may be polished, when necessary, using any suitable method, such as chemical polishing or mechanical polishing. By the polishing, the end surfaces of the filler 82 are preferably respectively made substantially flush with surfaces of the electrolytic plating films (41c, 51c).

Furthermore, on the first surface side of the laminated substrate 2, the seed film (41d) and the electrolytic plating film (41e) are formed in this order on the electrolytic plating film (41c) and the filler 82. At the same time, on the second surface side of the laminated substrate 2, the seed film (51d) and the electrolytic plating film (51e) are formed in this order on the electrolytic plating film (51c) and the filler 82. The seed films (41d, 51d) and the electrolytic plating films (41e, 51e) are formed, for example, using the same method as the seed films (41b, 51b) and the electrolytic plating films (41c, 51c). On the first insulating layer 40, a five-layer structure including the metal foil (41a), the seed film (41b), the electrolytic plating film (41c), the seed film (41d), and the electrolytic plating film (41e) is formed. On the second insulating layer 50, a five-layer structure including the metal foil (51a), the seed film (51b), the electrolytic plating film (51c), the seed film (51d), and the electrolytic plating film (51e) is formed. After that, as illustrated in FIG. 4G, the fifth conductor layer 41 and the sixth conductor layer 51 having desired conductor patterns are formed using a subtractive method that involves etching or the like using a mask on which wiring patterns are drawn.

At the same time, the first cover conductors 43 formed of the seed layer (41d) and the electrolytic plating layer (41e) are formed on the ends of the filler 82 on the first surface side (first insulating layer 40 side). The first cover conductors 43 have a five-layer structure including the metal foil layer (41a), the seed layer (41b), the electrolytic plating layer (41c), the seed layer (41d), and the electrolytic plating layer (41e). The second cover conductors 53 formed of the seed layer (51d) and the electrolytic plating layer (51e) are formed on the ends of the filler 82 on the second surface side (second insulating layer 50 side). The second cover conductors 53 have a five-layer structure including the metal foil layer (51a), the seed layer (51b), the electrolytic plating layer (51c), the seed layer (51d), and the electrolytic plating layer (51e).

As illustrated in FIG. 4H, a prepreg (60p) to be cured into the third insulating layer 60 is formed on the first surface side of the laminated substrate 2. A prepreg (70p) to be cured into the fourth insulating layer 70 is formed on the second surface side of the laminated substrate 2. The prepreg (60p) is formed on the first insulating layer 40 and the fifth conductor layer 41. The prepreg (70p) is formed on the second insulating layer 50 and the sixth conductor layer 51. The metal foil (61a) is formed on the prepreg (60p). The metal foil (71a) is formed on the prepreg (70p).

As illustrated in FIG. 4I, the prepreg (60p), the laminated substrate 2, and the prepreg (70p) are stacked in the position illustrated in FIG. 4H and then collectively pressed. Thermal curing may be performed simultaneously with the collective pressing, or after the pressing. Through the collective pressing, the prepregs (60p, 70p) are cured into the third insulating layer 60 and the fourth insulating layer 70. After the pressing, the fifth conductor layer 41 is embedded in the third insulating layer 60. After the pressing, the sixth conductor layer 51 is embedded in the fourth insulating layer 70. A laminated substrate 3 including the third insulating layer 60, the first insulating layer 40, the first resin substrate 20, the central insulating layer 10, the second resin substrate 30, the second insulating layer 50, and the fourth insulating layer 70 is formed.

As illustrated in FIG. 4J, the through-hole openings (90a) are formed in the laminated substrate 3. The through-hole openings (90a) are formed penetrating the metal foil (61a), the third insulating layer 60, the first insulating layer 40, the second conductor layer 22, the first resin substrate 20, the first conductor layer 21, the central insulating layer 10, the third conductor layer 31, the second resin substrate 30, the fourth conductor layer 32, the second insulating layer 50, the fourth insulating layer 70, and the metal foil (71a) of the laminated substrate 3. The through-hole openings (90a) are formed, for example, by drilling using a cutting device such as a drill. The through-hole openings (90a) may also be formed by laser irradiation. Furthermore, the holes (60a) are formed penetrating the metal foil (61a) and the third insulating layer 60 and exposing the first cover conductors 43. Similarly, the holes (70a) are formed penetrating the metal foil (71a) and the fourth insulating layer 70 and exposing the second cover conductors 53. The holes (60a, 70a) are formed, for example, by laser irradiation.

As illustrated in FIG. 4K, conductors are formed in the through-hole openings (90a) of the laminated substrate 3. A seed film is formed on the metal foil of the laminated substrate 3 and on inner walls of the through-hole openings. Specifically, a seed film (61b) is formed on the metal foil (61a) of the laminated substrate 3, a seed film (91b) is formed on the inner walls of the through-hole openings (90a), and a seed film (71b) is formed on the metal foil (71a). At the same time, a seed film (61b) is formed on the inner walls of the holes (60a), and a seed film (71b) is formed on the inner walls of the holes (70a). The seed films (61b, 91b, 71b) are formed simultaneously, and the metal films are formed, for example, by electroless plating or sputtering. An electrolytic plating film is formed using a metal layer serving as a seed film as a power feeding layer. The electrolytic plating films (61c, 91c, 71c) are formed on the seed films. The inner-wall conductor layer 91 formed of the seed film (91b) and the electrolytic plating film (91c) is formed on the inner walls of the through-hole openings. The electrolytic plating films (61c, 71c) fill the holes (60a, 70a). The first via conductors 62 are formed by the seed layer (61b) formed on the inner walls of the holes (60a) and the electrolytic plating layer (61c) filling the holes (60a). The second via conductors 72 are formed by the seed layer (71b) formed on the inner walls of the holes (70a) and the electrolytic plating layer (71c) filling the holes (70a).

The filler 92 is filled in cavities of the through-hole openings (90a). For example, a resin such as epoxy resin, acrylic resin, or phenolic resin is injected into each through-hole opening (80a) from one or both ends. The through-hole openings (90a) may be filled with, for example, a conductive paste containing conductive particles such as silver particles, instead of an insulating resin such as epoxy resin, as the filler 92. The insulating resin such as epoxy resin or the conductive paste used for the filler 92 is solidified, by heating or the like when necessary, to form the filler 92. The second through holes 90 are formed of the inner-wall conductor layer 91 and the filler 92 in the through-hole openings (80a). The end surfaces of the filler 92 after solidification may be polished, when necessary, using any suitable method, such as chemical polishing or mechanical polishing. By the polishing, the end surfaces of the filler 92 are preferably respectively made substantially flush with surfaces of the electrolytic plating films (61c, 71c).

Furthermore, on the first surface side of the laminated substrate 3, the seed film (61d) and the electrolytic plating film (61e) are formed in this order on the electrolytic plating film (61c) and the filler 92. At the same time, on the second surface side of the laminated substrate 3, the seed film (71d) and the electrolytic plating film (71e) are formed in this order on the electrolytic plating film (71c) and the filler 92. The seed films (61d, 71d) and the electrolytic plating films (61e, 71e) are formed, for example, using the same method as the seed films (61b, 71b) and the electrolytic plating films (61c, 71c). On the third insulating layer 60, a five-layer structure including the metal foil (61a), the seed film (61b), the electrolytic plating film (61c), the seed film (61d), and the electrolytic plating film (61e) is formed. On the fourth insulating layer 70, a five-layer structure including the metal foil (71a), the seed film (71b), the electrolytic plating film (71c), the seed film (71d), and the electrolytic plating film (71e) is formed. After that, as illustrated in FIG. 4L, the seventh conductor layer 61 and the eighth conductor layer 71 having desired conductor patterns are formed using a subtractive method that involves etching or the like using a mask on which wiring patterns are drawn.

At the same time, the third cover conductors 63 formed of the seed layer (61d) and the electrolytic plating layer (61e) are formed on the ends of the filler 92 on the first surface side (third insulating layer 60 side). The third cover conductors 63 have a five-layer structure including the metal foil layer (61a), the seed layer (61b), the electrolytic plating layer (61c), the seed layer (61d), and the electrolytic plating layer (61e). The fourth cover conductors 73 formed of the seed layer (71d) and the electrolytic plating layer (71e) are formed on the ends of the filler 92 on the second surface side (fourth insulating layer 70 side). The fourth cover conductors 73 have a five-layer structure including the metal foil layer (71a), the seed layer (71b), the electrolytic plating layer (71c), the seed layer (71d), and the electrolytic plating layer (71e).

As a result, as illustrated in FIG. 4L, the multilayer core substrate 100 is formed. The multilayer core substrate 100 is formed of a central insulating layer 10, a first-surface-side insulating layer 12, and a second-surface-side insulating layer 14, and has multiple first through holes 80, multiple second through holes 90, multiple first via conductors 62, multiple second via conductors 72, inner-layer conductor layers, and surface-layer conductor layers. The first-surface-side insulating layer 12 is formed of a first resin substrate 20, a first insulating layer 40, and a third insulating layer 60. The second-surface-side insulating layer 14 is formed of a second resin substrate 30, a second insulating layer 50, and a fourth insulating layer 70. The inner-layer conductor layers are the first conductor layer 21, the second conductor layer 22, the fifth conductor layer 41, the third conductor layer 31, the fourth conductor layer 32, and the sixth conductor layer 51, and the surface-layer conductor layers are the seventh conductor layer 61 and the eighth conductor layer 71. As a result, the inner-layer conductors are formed in the first through holes and the second through holes.

The length (H1) of the first through holes 80 and the length (H2) of the second through holes 90 satisfy the relationship of Formula 1. The first through holes 80 serve as power supply lines, and the second through holes 90 serve as signal lines.

H1<H2 (Formula 1)

FIG. 4M schematically illustrates a plan view of the multilayer core substrate 100 of FIG. 4L. As illustrated in FIG. 4M, when the multilayer core substrate 100 is viewed in plan, the multilayer core substrate 100 has a power supply region (PR) formed near a center and a signal region (SR) formed around the power supply region (PR). The multiple first through holes 80 and the component 200 are formed within the power supply region (PR). The multiple second through holes 90 are formed within the signal region (SR). The density of the first through holes 80 is higher than the density of the second through holes 90. The pitch of the first through holes 80 is shorter than the pitch of the second through holes 90.

The build-up layers are formed on both surfaces of the multilayer core substrate 100. The first build-up layer 110 is formed on the first surface (100F) of the multilayer core substrate 100. The second build-up layer 120 is formed on the second surface (100S) of the multilayer core substrate 100. For example, a film-like insulating resin (for example, epoxy resin) containing no reinforcing material is thermocompression bonded to the first surface (100F) and the second surface (100S), thereby forming the insulating layer 111 on the first surface (100F) side among the two insulating layers 111 and the insulating layer 121 on the second surface (100S) side among the two insulating layers 121. Through-hole openings are formed, for example using a CO₂ laser, at locations where the via conductors 113 or the via conductors 123 are to be formed in the insulating layer 111 and the insulating layer 121. A seed film made of a conductor, such as copper, is formed on inner walls of the through-hole openings and on surfaces of the insulating layers (111, 121) by electroless plating, sputtering, or the like. A plating resist having openings for forming a conductor layer is formed, and an electrolytic plating film is formed in the openings by electrolytic plating using the seed film as a power feeding layer. Through resist stripping and etching, a conductor layer 112 and a conductor layer 122, as well as via conductors 113 and via conductors 123, each including a seed layer and an electrolytic plating layer, are formed. That is, the conductor layer 112 on the first surface (100F) side among the two conductor layers 112 and the conductor layer 122 on the second surface (100S) side among the two conductor layers 122 are formed using a semi-additive method (SAP) without using a metal foil. Along with the conductor layers (112, 122), the via conductors 113 penetrating the insulating layer 111 on the first surface (100F) side and the via conductors 123 penetrating the insulating layer 121 on the second surface (100S) side are formed.

Furthermore, the surface-side insulating layers (111, 121) are formed using the same method as the insulating layer 111 on the first surface (100F) side and the insulating layer 121 on the second surface (100S) side. Further, the surface-side conductor layers (112, 122) are formed using the same method as the conductor layer 112 on the first surface (100F) side and the conductor layer 122 on the second surface (100S) side. Further, the via conductors (113, 123) penetrating the respective surface-side insulating layers (111, 121) are formed using the same method as the via conductors 113 penetrating the insulating layer 111 on the first surface (100F) side and the via conductors 123 penetrating the insulating layer 121 on the second surface (100S) side. In this way, the first build-up layer 110 and the second build-up layer 120 are formed. As a result, the wiring substrate 1 (FIG. 1) of the embodiment is obtained.

In the wiring substrate 1 of the embodiment, the length (H1) of the first through holes 80 and the length (H2) of the second through holes 90 satisfy the relationship of Formula 1, H1<H2.

When the length (H1) of the first through holes 80 and the length (H2) of the second through holes 90 satisfy the relationship of Formula 1, both effects of high-speed signal transmission and power supply reinforcement can be achieved.

Further, in the wiring substrate 1 of the embodiment, the first through holes 80 are mainly positioned at the center of the wiring substrate 1, and the second through holes 90 are mainly positioned at the outer periphery of the wiring substrate 1. The first through holes 80 serve as power supply lines, and the second through holes 90 serve as signal lines. The density of the first through holes 80 is higher than the density of the second through holes 90. The pitch of the first through holes 80 is shorter than the pitch of the second through holes 90. By forming the first through holes 80 and the second through holes 90 as described above, and by having the densities and pitches in the above-described relationships, warpage of the multilayer core substrate 100 is suppressed. Further, electrical connection reliability of the wiring substrate 1 is ensured.

Japanese Patent Application Laid-Open Publication No. 2010-166099 describes a printed wiring board in which conductor layers and interlayer resin insulating layers are alternately laminated on a core substrate. In the core substrate, outer-layer through holes are formed. Inner-layer through holes are formed within the outer-layer through holes. The outer-layer through holes and the inner-layer through holes have a coaxial structure.

It is thought that the printed wiring board of Japanese Patent Application Laid-Open Publication No. 2010-166099 cannot achieve both effects of high-speed signal transmission and power supply reinforcement.

A wiring substrate according to an embodiment of the present invention include: a multilayer core substrate; and a build-up layer. The multilayer core substrate is formed of a central insulating layer, a first-surface-side insulating layer, and a second-surface-side insulating layer, and includes multiple first through holes, multiple second through holes, and inner-layer conductors. The central insulating layer is formed of at least one resin substrate or insulating layer. The first-surface-side insulating layer is formed of at least N insulating layers (where N is an integer of 2 or more). The second-surface-side insulating layer is formed of at least N insulating layers (where N is an integer of 2 or more). A component is embedded on a first surface side of the multilayer core substrate. The first through holes and the second through holes are each connected to inner-layer conductors of at least one or more layers, and a length (H1) of the first through holes and a length (H2) of the second through holes satisfy a relationship of Formula 1, H1<H2.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a multilayer core substrate; a build-up layer formed on the multilayer core substrate; and
a component embedded in the multilayer core substrate such that the component is positioned on a first surface side of the multilayer core substrate,
wherein the multilayer core substrate includes a central insulating layer, a plurality of first-surface-side insulating layers formed on a first surface side of the central insulating layer, a plurality of second-surface-side insulating layers formed on a second surface side of the central insulating layer, a plurality of inner-layer conductors formed on the central insulating layer and the first-surface-side insulating layers and second-surface-side insulating layers, a plurality of first through holes formed in the multilayer core substrate such that each of the first through holes is connected to at least one of the inner-layer conductors, and a plurality of second through holes formed in the multilayer core substrate such that each of the second through holes is connected to at least one of the inner-layer conductors and that the first and second through holes satisfy H1<H2 where H1 is a length of each of the first through holes and H2 is a length of each of the second through holes.

2. The wiring substrate according to claim 1, wherein the first through holes are formed in a center portion of the multilayer core substrate, and the second through holes are formed in an outer periphery portion of the multilayer core substrate.

3. The wiring substrate according to claim 1, wherein the multilayer core substrate is formed such that the first through holes penetrate through the central insulating layer, M insulating layer or layers of the first-surface-side insulating layers where M is an integer between 1 and N−1 and N is a number of the first-surface-side insulating layers, and M insulating layer or layers of the second-surface-side insulating layers where M is an integer between 1 and N−1 and N is a number of the second-surface-side insulating layers.

4. The wiring substrate according to claim 1, wherein the multilayer core substrate is formed such that the second through holes penetrate through the central insulating layer, N insulating layers of the first-surface-side insulating layers, and N insulating layers of the second-surface-side insulating layers.

5. The wiring substrate according to claim 1, wherein the multilayer core substrate is formed such that the plurality of first through holes is a plurality of power supply lines and the plurality of second through holes is a plurality of signal lines.

6. The wiring substrate according to claim 1, wherein the multilayer core substrate is formed such that a density of the first through holes is higher than a density of the second through holes.

7. The wiring substrate according to claim 1, wherein the multilayer core substrate is formed such that a pitch of the first through holes is shorter than a pitch of the second through holes.

8. The wiring substrate according to claim 1, further comprising:
a plurality of via conductors formed on the plurality of first through holes, respectively.

9. The wiring substrate according to claim 1, wherein the multilayer core substrate has a power supply region and a signal region such that the component is positioned in the power supply region.

10. The wiring substrate according to claim 2, wherein the multilayer core substrate is formed such that the first through holes penetrate through the central insulating layer, M insulating layer or layers of the first-surface-side insulating layers where M is an integer between 1 and N−1 and N is a number of the first-surface-side insulating layers, and M insulating layer or layers of the second-surface-side insulating layers where M is an integer between 1 and N−1 and N is a number of the second-surface-side insulating layers.

11. The wiring substrate according to claim 2, wherein the multilayer core substrate is formed such that the second through holes penetrate through the central insulating layer, N insulating layers of the first-surface-side insulating layers, and N insulating layers of the second-surface-side insulating layers.

12. The wiring substrate according to claim 2, wherein the multilayer core substrate is formed such that the plurality of first through holes is a plurality of power supply lines and the plurality of second through holes is a plurality of signal lines.

13. The wiring substrate according to claim 2, wherein the multilayer core substrate is formed such that a density of the first through holes is higher than a density of the second through holes.

14. The wiring substrate according to claim 2, wherein the multilayer core substrate is formed such that a pitch of the first through holes is shorter than a pitch of the second through holes.

15. The wiring substrate according to claim 2, further comprising:
a plurality of via conductors formed on the plurality of first through holes, respectively.

16. The wiring substrate according to claim 2, wherein the multilayer core substrate has a power supply region and a signal region such that the component is positioned in the power supply region.

17. The wiring substrate according to claim 3, wherein the multilayer core substrate is formed such that the second through holes penetrate through the central insulating layer, N insulating layers of the first-surface-side insulating layers, and N insulating layers of the second-surface-side insulating layers.

18. The wiring substrate according to claim 3, wherein the multilayer core substrate is formed such that the plurality of first through holes is a plurality of power supply lines and the plurality of second through holes is a plurality of signal lines.

19. The wiring substrate according to claim 3, wherein the multilayer core substrate is formed such that a density of the first through holes is higher than a density of the second through holes.

20. The wiring substrate according to claim 3, wherein the multilayer core substrate is formed such that a pitch of the first through holes is shorter than a pitch of the second through holes.
